(19) United States
(12) Patent Application Publication
(10) Pub. No.: US 2026/0190913 A1
(43) Pub. Date: Jul. 2, 2026

(54) APPARATUS AND METHOD FOR BONDING SUBSTRATES

(71) Applicant: SEMES CO., LTD., Cheonan-si (KR)

(72) Inventors: Ji Young CHOI, Hwaseong-si (KR); Ki Hoon LIM, Bucheon-si (KR); Sung Gyu LEE, Suwon-si (KR); A Rah CHO, Daejeon (KR)

(21) Appl. No.: 19/350,313

(22) Filed: Oct. 6, 2025

(30) Foreign Application Priority Data
Dec. 30, 2024 (KR) 10-2024-0200458

(51) Int. Cl. H01L 21/67; B32B 37/00; B32B 38/00

(52) U.S. Cl. CPC H10P 72/0438; B32B 37/0046; B32B 2038/0076; B32B 2457/14

(57) ABSTRACT

The present disclosure provides an apparatus for bonding a substrate and a method for bonding a substrate. An apparatus for bonding a substrate according to an embodiment of the present disclosure includes an ultraviolet light irradiation chamber irradiating a plurality of substrates with ultraviolet light; and a substrate bonding chamber bonding the plurality of substrates irradiated with ultraviolet light by bringing the same into close contact with each other.

### CROSS-REFERENCE TO RELATED APPLICATION(S)

This application claims the benefit of a priority to Korean Patent Application No. 10-2024-0200458 filed on Dec. 30, 2024 in the Korean Intellectual Property Office, the entire disclosure of which is incorporated herein by reference for all purposes.

### BACKGROUND

The present disclosure relates to an apparatus for bonding a substrate and a method for bonding a substrate.

As semiconductor devices become more highly integrated, the use of a bonding substate, formed by bonding a plurality of substrates by a substrate bonding process, is increasing. In other words, 3D stacking technology is being applied to achieve high-density integration of semiconductor devices. The 3D stacking technology may dramatically improve chip performance by increasing a degree of integration thereof per unit area or reducing a length of a wiring, as compared to 2D integration technology.

However, in the prior art, since two substrates are bonded by baking the same at high temperatures for a long period of time after plasma treatment, there may be a problem that the bonding process takes a long time and the substrates may deteriorate due to long-term exposure to high temperatures.

### SUMMARY

The present disclosure has been created to solve the above-described problems, and an aspect of the present disclosure is to provide an apparatus for bonding a substrate and a method for bonding a substrate, which shortens a process time for bonding a substrate and prevents deterioration thereof due to long-term exposure to high temperatures.

In order to achieve the object, according to an aspect of the present disclosure, an apparatus for bonding a substrate includes an ultraviolet light irradiation chamber unit irradiating a substrate with ultraviolet light, wherein the substrate is provided in plural; and a substrate bonding chamber bonding the plurality of substrates irradiated with ultraviolet light by bringing the same into close contact with each other.

The ultraviolet light irradiation chamber unit may irradiate the substrate with ultraviolet light, to treat a surface of an inorganic film of the substrate, thereby hydrophilizing a terminal group of the surface of the inorganic film.

The ultraviolet light irradiation chamber unit may irradiate the substrate with ultraviolet light at a temperature of within a range of 100° C. to 200° C. for 1 to 5 minutes.

As an example, the ultraviolet light irradiation chamber unit may include a processing chamber in which the substrate is disposed; an ultraviolet light source irradiating the substrate with ultraviolet light; and a lamp house connected to the processing chamber, and having the ultraviolet light source disposed therein.

As another example, the ultraviolet light irradiation chamber unit may include a plurality of processing chambers in which the plurality of substrates are disposed; an ultraviolet light source disposed between the plurality of processing chambers, to irradiate the plurality of substrates with ultraviolet light; and a lamp house connecting the plurality of processing chambers, and having the ultraviolet light source disposed therein.

The substrate bonding chamber may covalently bond the plurality of substrates irradiated with ultraviolet light by heating the plurality of substrates while bringing the same into close contact with each other by a condensation reaction.

The substrate bonding chamber may include a first substrate support having a first heating plate vacuum-suctioning an upper surface of one of the plurality of substrates; and a second substrate support having a second heating plate supporting a lower surface of the other of the plurality of substrates, wherein at least one of the first substrate support and the second substrate support may be moved, to bring the plurality of substrates into close contact with each other.

After the plurality of substrates are bonded, one of the first substrate support and the second substrate support may release the vacuum suction of one of the plurality of vacuum-suctioned substrates.

According to another aspect of the present disclosure, an apparatus for bonding a substrate may be provided, the apparatus including an ultraviolet light irradiation chamber unit irradiating a plurality of substrates with ultraviolet light; and a substrate bonding chamber bonding the plurality of substrates irradiated with ultraviolet light by bringing the same into close contact with each other, wherein the ultraviolet light irradiation chamber unit includes two processing chambers having two substrates disposed therein; two support units disposed in the two processing chambers, and supporting the two substrates; an ultraviolet light source disposed between the two processing chambers, and irradiating the two substrates with ultraviolet light; a lamp house having the ultraviolet light source disposed therein; and two transparent windows installed between the two processing chambers and the lamp house, wherein the substrate bonding chamber includes a first substrate support having a first heating plate vacuum-suctioning an upper surface of one of the two substrates; and a second substrate support having a second heating plate supporting a lower surface of the other of the two substrates, wherein at least one of the first substrate support and the second substrate support is raised and lowered, to bring the two substrates irradiated with ultraviolet light into close contact with each other.

According to another aspect of the present disclosure, a method for bonding a substrate may be provided, the method including: an ultraviolet light irradiation operation of irradiating a plurality of substrates with ultraviolet light; and a substrate bonding operation of bonding the plurality of substrates irradiated with ultraviolet light by bringing the same into close contact with each other.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a drawing illustrating an example of an ultraviolet light irradiation chamber unit in an apparatus for bonding a substrate according to an embodiment of the present disclosure;

FIG. 2 is a drawing illustrating another example of an ultraviolet light irradiation chamber unit in an apparatus for bonding a substrate according to an embodiment of the present disclosure;

FIG. 3 is a drawing illustrating a process in which a substrate is bonded in a substrate bonding chamber of an apparatus for bonding a substrate according to an embodiment of the present disclosure;

FIG. 4 is a drawing illustrating that a substrate is bonded according to an embodiment of the present disclosure; and

FIG. 5 is a flowchart illustrating a method for bonding a substrate according to an embodiment of the present disclosure.

### DETAILED DESCRIPTION

Hereinafter, preferred embodiments of the present disclosure will be described in detail so that those skilled in the art could easily practice the present disclosure with reference to the accompanying drawings. However, in describing a preferred embodiment of the present disclosure in detail, if it is determined that a detailed description of a related known function or configuration may unnecessarily obscure the subject matter of the present disclosure, the detailed description will be omitted. In addition, the same reference numerals are used throughout the drawings for parts having similar functions and actions. In addition, in the present specification, terms such as ‘upper,’ ‘upper portion,’ ‘upper surface,’ ‘lower,’ ‘lower portion,’ ‘lower surface,’ ‘side surface,’ and the like are based on the drawings, and in practice, it may be different depending on a direction in which the components are disposed.

In addition, throughout the specification, when a part is said to be ‘connected’ to another part, this is not only when it is ‘directly connected,’ but also when it is ‘indirectly connected’ with other components therebetween. In addition, ‘including’ a certain component means that other components may be further included without excluding other components unless otherwise stated.

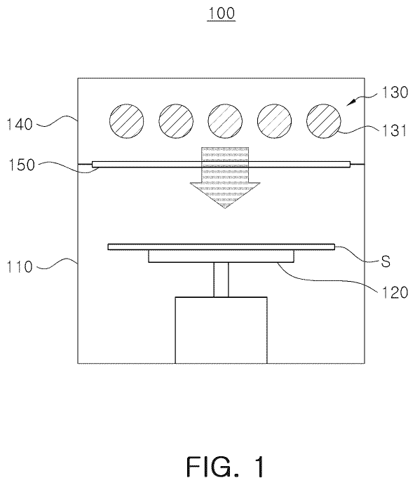

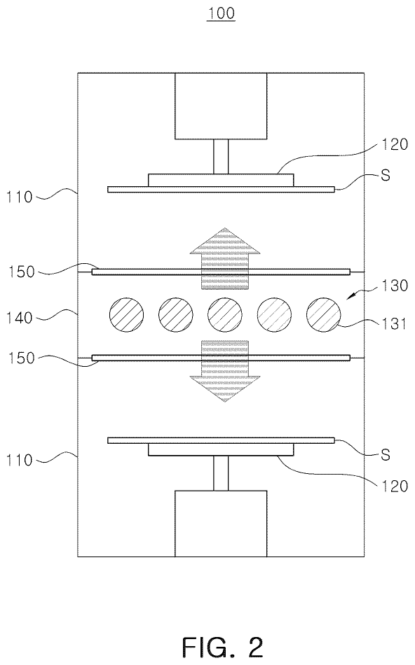

FIG. 1 is a drawing illustrating an example of an ultraviolet light irradiation chamber unit in an apparatus for bonding a substrate according to an embodiment of the present disclosure, and FIG. 2 is a drawing illustrating another example of an ultraviolet light irradiation chamber unit in an apparatus for bonding a substrate according to an embodiment of the present disclosure.

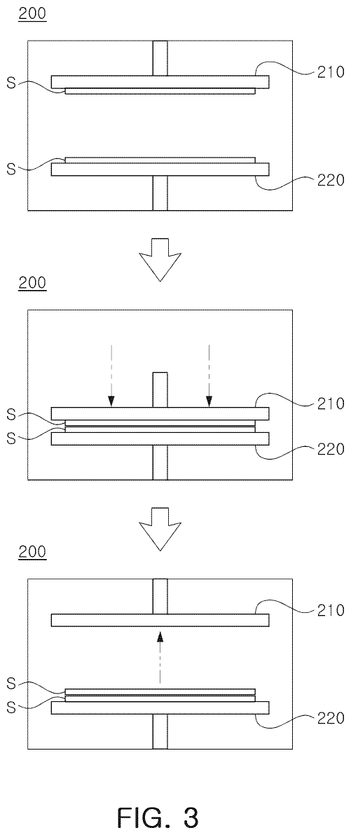

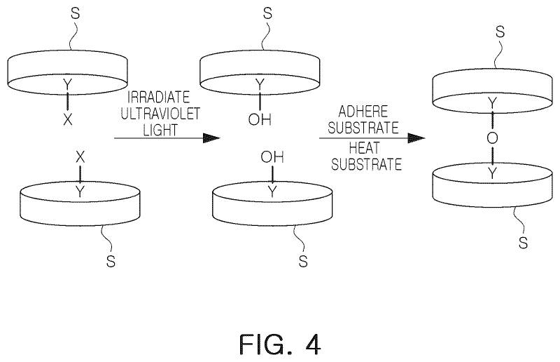

In addition, FIG. 3 is a drawing illustrating a process in which a substrate is bonded in a substrate bonding chamber of an apparatus for bonding a substrate according to an embodiment of the present disclosure, and FIG. 4 is a drawing illustrating that a substrate is bonded according to an embodiment of the present disclosure.

Referring to the drawing, an apparatus for bonding a substrate according to an embodiment of the present disclosure includes an ultraviolet light irradiation chamber unit 100 and a substrate bonding chamber 200.

The ultraviolet light irradiation chamber unit 100 irradiates a plurality of substrates(S) with ultraviolet light.

The substrate bonding chamber 200 bonds a plurality of substrates(S) irradiated with ultraviolet light by bringing the plurality of substrates(S) into close contact with each other.

Specifically, as illustrated in FIGS. 1, 2, and 4, the ultraviolet light irradiation chamber unit 100 may irradiate the substrate(S) with ultraviolet light to treat a surface of an inorganic film (Y) of the substrate(S), thereby hydrophilizing a terminal group (X) of the surface of the inorganic film (Y).

In this case, for example, the inorganic film (Y) of the substrate(S) may include inorganic substances such as silicon, tin, tungsten, and aluminum, and may also include a small amount of organic substances such as carbon, hydrogen, oxygen, and nitrogen. In addition, the terminal group (X) on the surface of the inorganic film (Y) may be, for example, an alkyl group (—(CH)ₙCH₃) or an alkoxy group (−0(CH)ₙCH₃).

More specifically, the ultraviolet light irradiation chamber unit 100 may be configured to irradiate the substrate (S) with ultraviolet light at a temperature within a range of 100° C. to 200° C. for 1 to 5 minutes.

If ultraviolet light are irradiated onto the substrate(S) at a temperature of lower than 100° C. or for less than 1 minute, since the generation of hydroxyl groups is insufficient due to insufficient activation of a chemical reaction by ultraviolet light, surface treatment of the inorganic film (Y) of the substrate(S) may not be completely performed.

That is, if ultraviolet light are irradiated onto the substrate(S) at a temperature lower than 100° C. or for less than 1 minute, the surface treatment may be performed only on a portion of the inorganic film (Y) of the substrate (S), and thus, uniform surface treatment may not be performed on the inorganic film (Y) of the substrate(S) as a whole.

In addition, if ultraviolet light are irradiated onto the substrate(S) at a temperature exceeding 200° C. or for more than 5 minutes, other films formed on the substrate (S) may deteriorate or be deformed due to loss of thermal stability.

According to the prior art, although not illustrated in the drawing, surface treatment of the inorganic film of the substrate is performed to bond a plurality of substrates, by spraying water on the substrate and then performing plasma treatment, a terminal group of the surface of the inorganic film may be hydrophilized.

Such a hydrophilization treatment process takes approximately 1 hour or more to hydrophilize the terminal group, and furthermore, despite the long treatment time, the surface treatment may not be uniformly performed on the entire inorganic film of the substrate.

In addition, the prior art has the following limitations when the hydrophilic treatment process described above is completed.

First, since the surface treatment of the inorganic film is not sufficiently activated by the conventional hydrophilic treatment, that is, the surface treatment of the inorganic film is not sufficiently performed, the substrate bonding time after the surface treatment takes 1 hour or more, there is a limitation in that the production yield is reduced according to the conventional technology.

Furthermore, in the process for bonding a plurality of substrates after the conventional hydrophilic treatment, a plurality of substrates are brought into close contact with each other and then subjected to high-temperature heat treatment, i.e., high-temperature baking, but, since the different inorganic films formed on the substrate have different coefficients of thermal expansion, if the substrate bonding time takes 1 hour or more, there is a limitation in that the inorganic films may deteriorate or be deformed. In other words, long-term exposure to high temperatures reduces physical and chemical stability of the inorganic film, causing deterioration or deformation thereof, which ultimately leads to a limitation in production yield.

In contrast, in the present disclosure, before bonding a plurality of substrates(S) by bringing the substrates(S) into close contact with each other, by hydrophilizing a terminal group (Y) of a surface of an inorganic film (Y) of the substrate(S) by ultraviolet light irradiation, as illustrated in FIGS. 1, 2, and 4, the production yield may be improved by hydrophilizing the terminal group (X) of the surface of the inorganic film (Y) in a significantly faster time, compared to a hydrophilization treatment according to the prior art.

Furthermore, since the surface treatment of the inorganic film (Y) of the substrate(S) is much more actively performed than in the prior art, a substrate bonding time is significantly shorter than in the prior art, at about 2 minutes. Accordingly, in the present disclosure, even if inorganic films (Y) formed of different materials formed on the substrate(S) have different coefficients of thermal expansion, since the inorganic films (Y) are not exposed to high temperatures for a long time, there is little deterioration or deformation of other inorganic films (Y) on the substrate(S), which ultimately improves the production yield.

Meanwhile, the ultraviolet light irradiation chamber unit 100 of the present disclosure may include a processing chamber 110, an ultraviolet light source 130, and a lamp house 140 as shown in FIG. 1 as an example.

The processing chamber 110 has a substrate(S) disposed therein. The substrate(S) may be supported by a support unit.

In addition, the ultraviolet light source 130 irradiates ultraviolet light onto the substrate(S). The ultraviolet light source (130) may be manufactured as an excimer lamp or a laser type in a wavelength range of 200 nm or less. The ultraviolet light source 130 may include a plurality of lamps 131.

In addition, the lamp house 140 is connected to the processing chamber 110, and an ultraviolet light source 130 is disposed therein. A transparent window 150 may be disposed between the processing chamber 110 and the lamp house 140.

As another example, as shown in FIG. 2, the ultraviolet light irradiation chamber unit 100 of the present disclosure may irradiate a plurality of substrates(S) with ultraviolet light from one ultraviolet light source 130, thereby efficiently utilizing ultraviolet light emitted from the ultraviolet light source 130 without wastes, and further increasing productivity.

An ultraviolet lamp 131 may be used as the ultraviolet light source 130. In this case, the ultraviolet light source 130 has a structure that irradiates ultraviolet light in a 360-degree direction, i.e., in all directions.

In order to efficiently utilize ultraviolet light radiated in all directions as described above, the present disclosure may be configured to irradiate ultraviolet light onto a plurality of substrates(S) with ultraviolet light sources.

Specifically, the ultraviolet light irradiation chamber unit 100 may include a plurality of processing chambers 110, a plurality of support units 120, an ultraviolet light source 130, a lamp house 140, and a plurality of transparent windows 150.

A plurality of processing chambers 110 have a plurality of substrates(S) disposed therein.

As an example, the plurality of processing chambers 110 may include two processing chambers 110, as illustrated in the drawing. In this case, the two processing chambers 110 may be disposed to be spaced apart from each other in a longitudinal direction.

In addition, a plurality of support units 120 may be disposed in a plurality of processing chambers 110.

As an example, the plurality of support units 120 may include two support units 120, as illustrated in the drawing. The two support units 120 may be disposed in two processing chambers 110. That is, one support unit 120 may be disposed in one processing chamber 110. In this case, each of the plurality of support units 120 only needs to firmly and stably support and fix the substrate(S), and a specific structure thereof is not limited by the present disclosure.

In addition, an ultraviolet light source 130 may be disposed between the plurality of processing chambers 110 to irradiate ultraviolet light onto the plurality of substrates (S).

As an example, the ultraviolet light source 130 may be disposed between the two processing chambers 110 as shown in the drawing to irradiate the two substrates(S) with ultraviolet light.

More specifically, the ultraviolet light source 130 may include a plurality of ultraviolet lamps 131 disposed to be spaced apart from each other in a horizontal direction, as illustrated in the drawing.

A processing chamber 110 may be disposed on each of upper and lower sides of the plurality of ultraviolet lamps 131, so that ultraviolet light radiated from the plurality of ultraviolet lamps 131 to the upper and lower sides thereof may be efficiently utilized.

In addition, the ultraviolet light source 130 may be disposed inside the lamp house 140.

The lamp house 140 may have a structure connecting a plurality of processing chambers 110, and as an example, may connect two processing chambers 110 as shown in the drawing.

In addition thereto, a plurality of transparent windows 150 may be installed between a plurality of processing chambers 110 and a lamp house 140.

As an example, the plurality of transparent windows 150 may include two transparent windows 150 installed between the two processing chambers 110 and the lamp house 140, as shown in the drawings. That is, one transparent window 150 may be disposed between the lamp house 140 and one processing chamber 110, and the remaining transparent windows 150 may be disposed between the lamp house 140 and the remaining processing chambers 110. In this case, each of the plurality of transparent windows 150 may utilize a quartz window.

Furthermore, although not shown in the drawing, processing chambers may be disposed on each of the upper, lower, left, and right sides of the plurality of Ultraviolet lamps, so that ultraviolet light radiated from the plurality of ultraviolet lamps to the upper, lower, left, and right sides thereof may be efficiently utilized.

A substrate bonding chamber 200 is configured to bond a plurality of substrates(S) irradiated with ultraviolet light by bringing the plurality of substrates(S) into close contact with each other.

Specifically, as illustrated in FIGS. 3 and 4, the substrate bonding chamber 200 may covalently bond the plurality of substrates(S) irradiated with ultraviolet light by heating the plurality of substrates(S) while bringing the same into close contact with each other by a condensation reaction.

In the ultraviolet light irradiation chamber unit 100, a surface of an inorganic film (Y) of the plurality of substrates(S) irradiated with ultraviolet light is hydrophilic, and then in the substrate bonding chamber 200, the plurality of substrates(S) are bonded by being heated while being brought into close contact with each other.

That is, in the substrate bonding chamber 200, the plurality of substrates(S) irradiated with ultraviolet light are brought into close contact with each other and heated at the same time, and as a condensation reaction occurs during the heating process, the plurality of substrates(S) are firmly bonded by covalent bonding of the terminal group (X) of the inorganic film (Y).

To this end, the substrate bonding chamber 200 may specifically include a first substrate support 210 and a second substrate support 220.

To this end, the substrate bonding chamber 200 may specifically include a first substrate support 210 and a second substrate support 220.

Such a first heating plate may vacuum-suction an upper surface of one of the plurality of substrates(S), and may heat the substrate(S) by having a heater, such as a heating wire, built therein.

In addition, the second substrate support 220 may have a second heating plate (not shown).

Such a second heating plate can may vacuum-suction an upper surface of the other of the plurality of substrates (S), and may heat the substrate(S) by having a heater, such as a heating wire, built therein.

In addition, the first substrate support 210 and the second substrate support 220 may be configured so that at least one of the first substrate support 210 and the second substrate support 220 are moved, to bring the plurality of substrates(S) into close contact with each other.

As an example, the substrate bonding chamber 200 may be configured to bond two substrates(S) by brining the two substrates(S) into close contact with each other as shown in the drawing.

In this case, the first substrate support 210 may be disposed on an upper side thereof to support and fix one of the two substrates(S) and heat the same, and the second substrate support 220 may be disposed on a lower side thereof to support and fix the other of the two substrates(S) and heat the same.

In addition, the first substrate support 210 and the second substrate support 220 may be configured so that at least one of the first substrate support 210 and the second substrate support 220 may be raised and lowered to bring the two substrates(S) disposed on the upper and lower sides thereof into close contact with each other.

After the plurality of substrates(S) are bonded, one of the first substrate support 210 and the second substrate support 220 may release the vacuum suction of one of the bonded plurality of substrates(S).

That is, after two substrates(S) are bonded as illustrated in the middle drawing of FIG. 3, the vacuum suction of one of the two bonded substrates(S) may be released by the first substrate support 210, as illustrated in the bottommost drawing of FIG. 3.

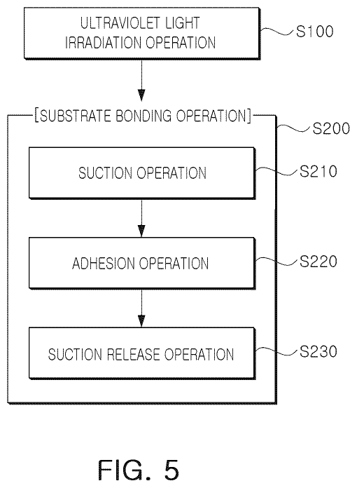

The ultraviolet light irradiation, and adhesion and bonding of the substrate(S) performed by the apparatus for bonding a substrate of the present disclosure described above are summarized as follows based on the flow chart of the method for bonding a substrate illustrated in FIG. 5.

Referring to FIGS. 2 to 4 along with FIG. 5, a method for bonding a substrate according to an embodiment of the present disclosure may include an ultraviolet light irradiation operation (S100) and a substrate bonding operation (S200).

First, the ultraviolet light irradiation operation (S100) is an operation of irradiating a plurality of substrates(S) with ultraviolet light.

In the ultraviolet light irradiation operation (S100), ultraviolet light is irradiated onto the plurality of substrates(S), to treat a surface of an inorganic film (Y) of the plurality of substrates(S), thereby hydrophilizing a terminal group (X) of the surface of the inorganic film (Y).

In addition, in the ultraviolet light irradiation operation (S100), the plurality of substrates(S) may be irradiated with ultraviolet light at a temperature within a range of 100° C. to 200° C. for 1 to 5 minutes.

Furthermore, in the ultraviolet light irradiation operation (S100), a plurality of substrates(S) in a plurality of processing chambers 110 disposed with a lamp house 140 therebetween may be irradiated with ultraviolet light by an ultraviolet light source 130 built in the lamp house 140.

Next, the substrate bonding operation (S200) is an operation of bonding a plurality of substrates(S) irradiated with ultraviolet light by bringing the plurality of substrates(S) into close contact with each other.

The substrate bonding operation (S200) may include a suction operation (S210) and an adhesion operation (S220).

The suction operation (S210) is an operation of vacuum-suctioning a plurality of substrates(S) onto a plurality of substrate supports. In this case, the plurality of substrate supports may be the first substrate support 210 and the second substrate support 220 described above.

The following adhesion operation (S220) is an operation of adhering a plurality of substrates(S) by moving at least one of the plurality of substrate supports.

In this case, in the adhesion operation (S220), a plurality of substrates(S) are heated by a plurality of heating plates of a plurality of substrate supports. Furthermore, the plurality of substrates(S) may also be pre-heated in the suction operation (S210).

Specifically, in the adhesion operation (S220), a plurality of substrates(S) may be covalently bonded by heating the plurality of substrates(S) while bringing the same into close contact with each other by a condensation reaction.

In addition thereto, the substrate bonding operation (S200) may further include a suction release operation (S230).

The suction release operation (S230) is an operation of releasing one of the plurality of substrates(S) from one of the plurality of substrate supports, after the plurality of substrates(S) are bonded.

As set forth above, according to the present disclosure, by hydrophilizing a terminal group of a surface of an inorganic film of a substrate by ultraviolet light irradiation, as the terminal group of the surface of the inorganic film is hydrophilized in a short period time, production yield thereof may be improved.

Since the surface treatment of the inorganic film is activated by the ultraviolet light irradiation described above, a substrate bonding time takes a short time, and furthermore, since it is not exposed to high temperatures for a long time, there is almost no deterioration of the inorganic films of the substrate, which ultimately improves the production yield.

While exemplary embodiments have been shown and described above, it will be apparent to those skilled in the art that modifications and variations could be made without departing from the scope of the present invention as defined by the appended claims.

1. An apparatus for bonding a substrate, comprising:
an ultraviolet light irradiation chamber unit irradiating a substrate with ultraviolet light, wherein a substrate is provided in plural; and
a substrate bonding chamber bonding the plurality of substrates irradiated with ultraviolet light by bringing the same into close contact with each other.

2. The apparatus for bonding a substrate of claim 1, wherein the ultraviolet light irradiation chamber unit irradiates the substrate with ultraviolet light, to treat a surface of an inorganic film of the substrate, thereby hydrophilizing a terminal group of the surface of the inorganic film.

3. The apparatus for bonding a substrate of claim 2, wherein the ultraviolet light irradiation chamber unit irradiates the substrate with ultraviolet light at a temperature within a range of 100°C to 200°C for 1 to 5 minutes.

4. The apparatus for bonding a substrate of claim 1, wherein the ultraviolet light irradiation chamber unit comprises
a processing chamber in which the substrate is disposed;
an ultraviolet light source irradiating the substrate with ultraviolet light; and
a lamp house connected to the processing chamber, and having the ultraviolet light source disposed therein.

5. The apparatus for bonding a substrate of claim 1, wherein the ultraviolet light irradiation chamber unit comprises
a plurality of processing chambers in which the plurality of substrates are disposed;
an ultraviolet light source disposed between the plurality of processing chambers, to irradiate the plurality of substrates with ultraviolet light; and
a lamp house connecting the plurality of processing chambers, and having the ultraviolet light source disposed therein.

6. The apparatus for bonding a substrate of claim 1, wherein the substrate bonding chamber covalently bonds the plurality of substrates irradiated with ultraviolet light by heating the plurality of substrates while bringing the same into close contact with each other by a condensation reaction.

7. The apparatus for bonding a substrate of claim 1, wherein the substrate bonding chamber comprises
a first substrate support having a first heating plate vacuum-suctioning an upper surface of one of the plurality of substrates; and
a second substrate support having a second heating plate supporting a lower surface of the other of the plurality of substrates,
wherein at least one of the first substrate support and the second substrate support is moved, to bring the plurality of substrates into close contact with each other.

8. The apparatus for bonding a substrate of claim 7, wherein one of the first substrate support and the second substrate support releases the vacuum-suction of one of the plurality of vacuum-suctioned substrates, after the plurality of substrates are bonded.

9. An apparatus for bonding a substrate, comprising:
an ultraviolet light irradiation chamber unit irradiating a plurality of substrates with ultraviolet light; and
a substrate bonding chamber bonding the plurality of substrates irradiated with ultraviolet light by bringing the plurality of substrates into close contact with each other,
wherein the ultraviolet light irradiation chamber unit includes
two processing chambers having two substrates disposed therein;
two support units disposed in the two processing chambers, and supporting the two substrates;
an ultraviolet light source disposed between the two processing chambers, and irradiating the two substrates with ultraviolet light;
a lamp house having the ultraviolet light source disposed therein; and
two transparent windows installed between the two processing chambers and the lamp house,
wherein the substrate bonding chamber includes
a first substrate support having a first heating plate vacuum-suctioning an upper surface of one of the two substrates; and
a second substrate support having a second heating plate supporting a lower surface of the other of the two substrates,
wherein at least one of the first substrate support and the second substrate support is raised and lowered, to bring the two substrates irradiated with ultraviolet light into close contact with each other.

10. The apparatus for bonding a substrate of claim 9, wherein the ultraviolet light source irradiates the two substrates with ultraviolet light, to treat a surface of inorganic films of the two substrates, thereby hydrophilizing terminal groups of the surface of the inorganic films.

11. The apparatus for bonding a substrate of claim 10, wherein the ultraviolet light source irradiates the two substrates with ultraviolet light at a temperature within a range of 100°C to 200°C for 1 to 5 minutes.

12. The apparatus for bonding a substrate of claim 9, wherein the first substrate support and the second substrate support are covalently bonded by heating the two substrates irradiated with ultraviolet light while bringing the same into close contact with each other by a condensation reaction.

13. The apparatus for bonding a substrate of claim 1, wherein one of the first substrate support and the second substrate releases the vacuum-suction of one of the two bonded substrates, after the two substrates are bonded.

14.-20. (canceled)
